(19) United States
(12) Patent Application Publication
(10) Pub. No.: US 2023/0044391 A1
(43) Pub. Date: Feb. 9, 2023

(54) SELECTIVE SILICIDE DEPOSITION FOR 3-D DRAM

(71) Applicant: Applied Materials, Inc., Santa Clara, CA (US)

(72) Inventors: Nicolas Breil, Alviso, CA (US); Chang Seok Kang, Santa Clara, CA (US)

(73) Assignee: Applied Materials, Inc., Santa Clara, CA (US)

(21) Appl. No.: 17/879,091

(22) Filed: Aug. 2, 2022

Related U.S. Application Data
(60) Provisional application No. 63/228,762, filed on Aug. 3, 2021.

(51) Int. Cl. H01L 27/108

(52) U.S. Cl. CPC H01L 27/1085; H01L 27/10805; H01L 27/10873; H01L 27/10885

(57) ABSTRACT

Described are memory devices having a metal silicide, resulting in a low resistance contact. Methods of forming a memory device are described. The methods include forming a metal silicide layer on a semiconductor material layer on a memory stack, the semiconductor material layer having a capacitor side and a bit line side. A capacitor is then formed on the capacitor side of the metal silicide layer, and a bit line is formed on the bit line side of the metal silicide layer.

### CROSS-REFERENCE TO RELATED APPLICATIONS

This application claims priority to U.S. Provisional Application No. 63/228,762, filed Aug. 3, 2021, the entire disclosure of which is hereby incorporated by reference herein.

### TECHNICAL FIELD

Embodiments of the present disclosure pertain to the field of electronic devices and electronic device manufacturing. More particularly, embodiments of the disclosure provide a three-dimensional (3D) dynamic random-access memory cell.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices. The formation of a low resistance contact between the active area and the 3D DRAM bottom electrode is essential for performance of the device.

There is a need in the art, therefore, for memory devices and methods of forming memory devices that have low resistance contacts.

### SUMMARY

One or more embodiments of the disclosure are directed to methods of forming a memory device. In one or more embodiments, a method of forming a memory device comprises: forming a metal silicide layer on a semiconductor material layer on a memory stack, the semiconductor material layer having a capacitor side and a bit line side; forming a capacitor on the capacitor side of the metal silicide layer; and forming a bit line on the bit line side of the metal silicide layer.

Additional embodiments of the disclosure are directed to directed to methods of forming a memory device. In one or more embodiments, a method of forming a memory device comprises: forming a memory stack, the memory stack comprising a sacrificial layer, and alternating layers of a first material layer, a second material layer, and a semiconductor material layer; forming an active opening through the memory stack and recessing the first material layer through the active opening to form a recessed region; depositing a gate oxide layer on the second material layer; forming a word line in the recessed region, the word line comprising one or more of a barrier layer and a word line metal; depositing a fill material in the active opening; forming a slit pattern opening through the memory stack; forming a capacitor opening by recessing the second material layer and the semiconductor material layer through the slit pattern opening; forming a metal silicide layer on the semiconductor material layer; forming a capacitor in the capacitor opening; forming a bit line opening in the fill material; and forming a bit line in the bit line opening.

Further embodiments of the disclosure are directed to a non-transitory computer readable medium including instructions, that, when executed by a controller of a processing chamber, causes the processing chamber to perform the operations of: form a memory stack, the memory stack comprising a sacrificial layer, and alternating layers of a first material layer, a second material layer, and a semiconductor material layer; form an active opening through the memory stack and recessing the first material layer through the active opening to form a recessed region; deposit a gate oxide layer on the second material layer; form a word line in the recessed region, the word line comprising one or more of a barrier layer and a word line metal; deposit a fill material in the active opening; form a slit pattern opening through the memory stack; form a capacitor opening by recessing the second material layer and the semiconductor material layer through the slit pattern opening; form a metal silicide layer on the semiconductor material layer; form a capacitor in the capacitor opening; form a bit line opening in the fill material; and form a bit line in the bit line opening.

Additional embodiments of the disclosure are directed to directed to methods of forming a semiconductor device. In one or more embodiments, the method comprises: forming a film stack on a substrate, the film stack comprising a plurality of alternating layers of a semiconductor material layer and a dielectric layer; patterning the film stack to form an opening, the opening extending from a top surface of the stack to the substrate and having an aspect ratio of greater than or equal to 10:1; recessing the semiconductor material layer through the opening to form a recessed semiconductor material layer; and selectively depositing a metal layer on the recessed semiconductor material layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments;

FIG. 2A illustrates a cross-sectional view of a memory device according to one or more embodiments of the disclosure;

FIG. 2B illustrates a cross-sectional view of a memory device according to one or more embodiments of the disclosure;

FIG. 2C illustrates a cross-sectional view of a memory device according to one or more embodiments of the disclosure;

FIG. 2D illustrates a cross-sectional view of a memory device according to one or more embodiments of the disclosure;

FIG. 2E illustrates a cross-sectional view of a memory device according to one or more embodiments of the disclosure;

FIG. 2F illustrates a cross-sectional view of a memory device according to one or more embodiments of the disclosure;

FIG. 2G illustrates a cross-sectional view of a memory device according to one or more embodiments of the disclosure;

FIG. 2H illustrates a cross-sectional view of a memory device according to one or more embodiments of the disclosure;

FIG. 2I illustrates a cross-sectional view of a memory device according to one or more embodiments of the disclosure;

FIG. 2J illustrates a cross-sectional view of a memory device according to one or more embodiments of the disclosure;

FIG. 2K illustrates a cross-sectional view of a memory device according to one or more embodiments of the disclosure;

FIG. 2L illustrates a cross-sectional view of a memory device according to one or more embodiments of the disclosure;

FIG. 2M illustrates a cross-sectional view of a memory device according to one or more embodiments of the disclosure;

FIG. 2N illustrates a cross-sectional view of a memory device according to one or more embodiments of the disclosure;

FIG. 2O illustrates a cross-sectional view of a memory device according to one or more embodiments of the disclosure;

FIG. 2P illustrates a cross-sectional view of a memory device according to one or more embodiments of the disclosure;

FIG. 2Q illustrates a cross-sectional view of a memory device according to one or more embodiments of the disclosure; and

FIG. 3 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been descried in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used in this specification and the appended claims, the terms “precursor”, “reactant”, “reactive gas” and the like are used interchangeably to refer to any gaseous species that can react with the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, the term “dynamic random access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

In one or more embodiments, memory devices are provided which have a metal silicide layer, advantageously forming a low resistance contact for 3D DRAM. Forming a high-quality silicide on a 3D DRAM active area is challenging due to the lack or a direct opening. Additionally, the deposition of a silicide is challenging. PVD is not an option due to the non-line-of-sight property of the structure. CVD, on the other hand, would occupy a large amount of real estate, reduce the volume of the cavity, and thus the capacitance of the device. Accordingly, one or more embodiments provide a selective deposition method for forming the metal silicide.

In one or more embodiments, metal deposition and other processes can be carried out in an isolated environment (e.g., a cluster process tool). Accordingly, some embodiments of the disclosure provide integrated tool systems with related process modules to implement the methods.

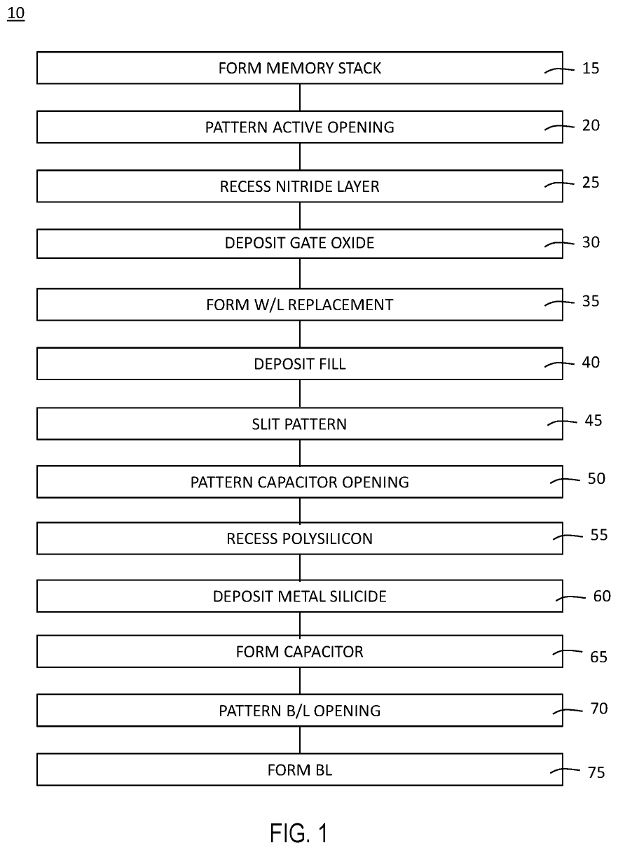

FIG. 1 illustrates a process flow diagram for a method 10 that can include any or all of the processes illustrated. Additionally, the order of the individual processes can be varied for some portions. The method 10 can start at any of the enumerated processes without deviating from the disclosure. With reference to FIG. 1, at operation 15, a memory stack is formed. At operation 20, an active opening is patterned into the memory stack. At operation 25, the first material layer, e.g., nitride layers, may be recessed through the active opening. At operation 30, a gate oxide is deposited. At operation 35, a word line replacement is formed. At operation 40, an oxide is deposited. At operation 45, the memory stack is slit patterned. At operation 50, a capacitor opening is patterned. At operation 55, the semiconductor material layer is recessed through the capacitor opening. At operation 60, a metal silicide layer is deposited. At operation 65, a capacitor is formed. At operation 70, a bit line opening is patterned. At operation 75, a bit line is formed.

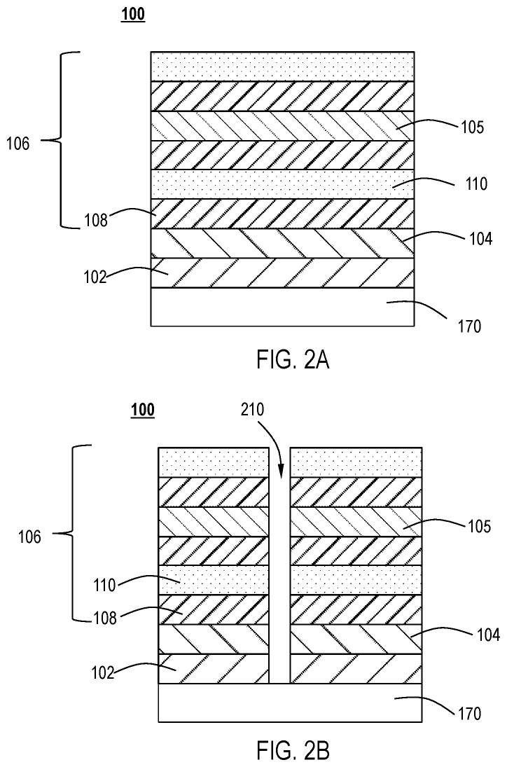

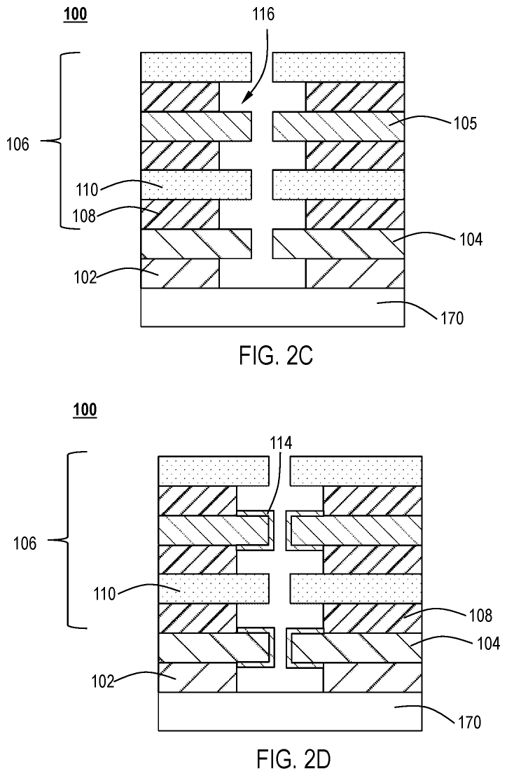

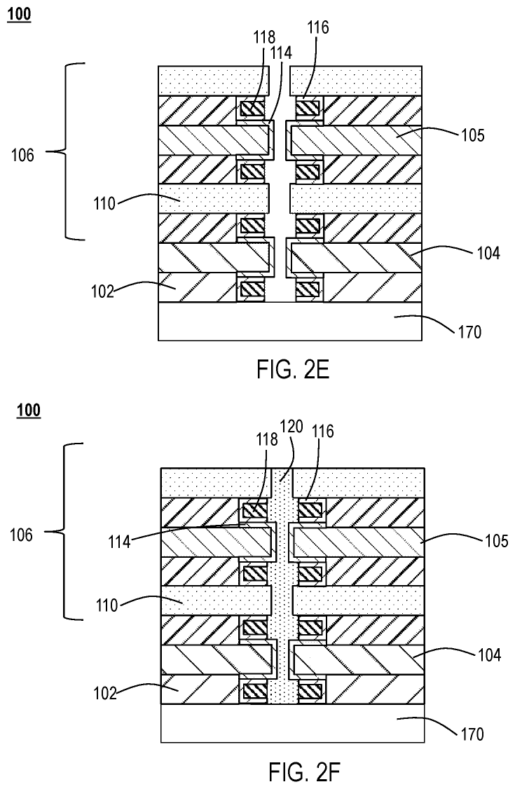

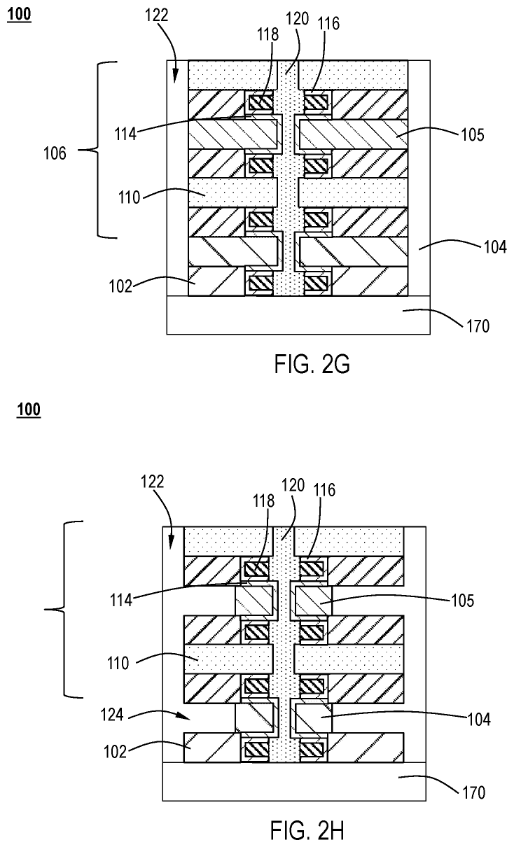

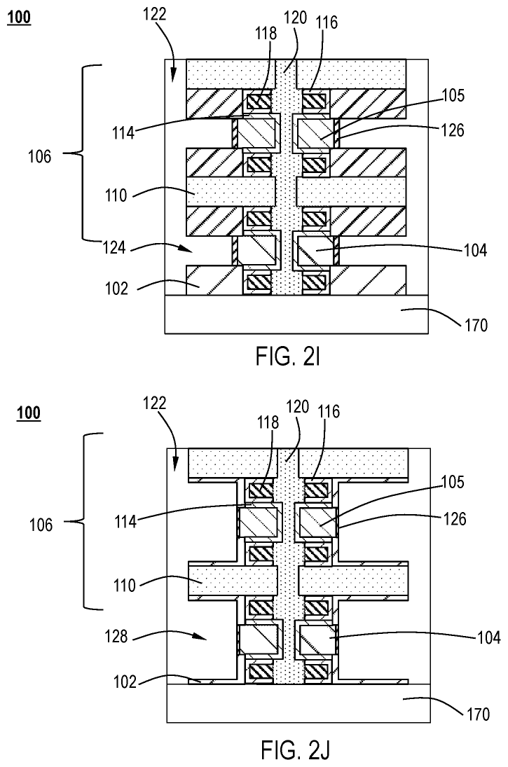

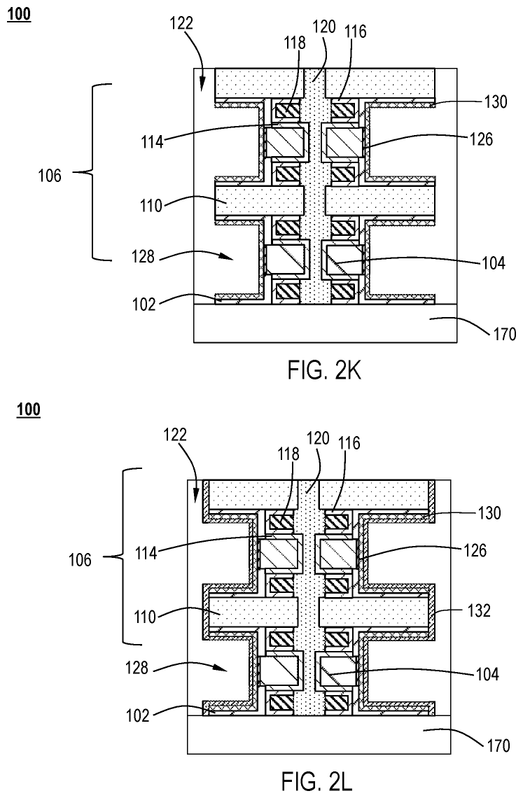

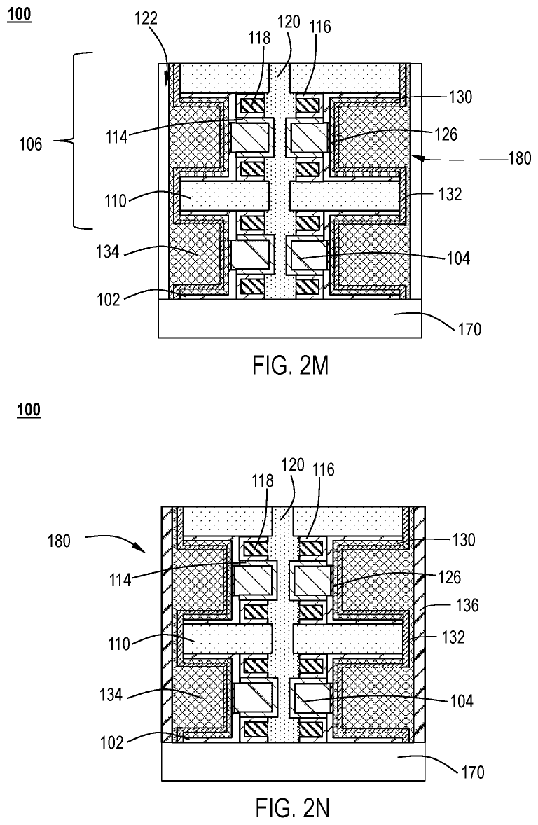

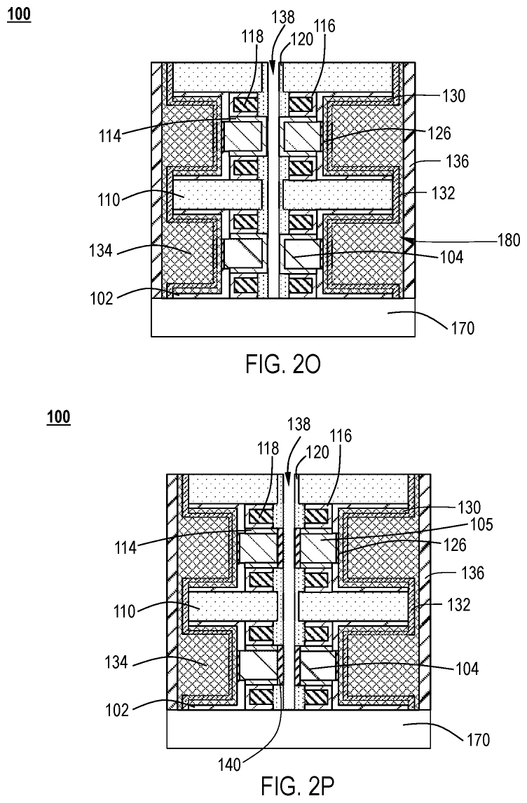

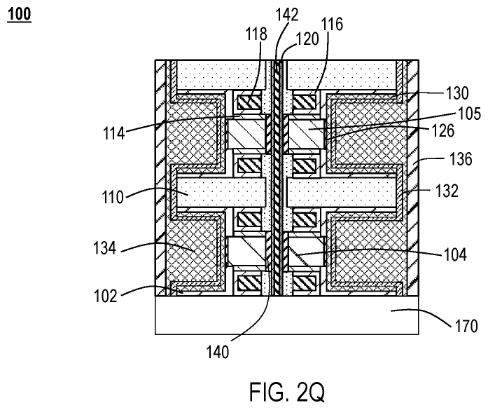

FIGS. 2A through 2Q illustrate cross-sectional views of a memory device according to one or more embodiments.

With reference to FIG. 2A, an initial or starting mold of an electronic device 100 is formed in accordance with one or more embodiments of the disclosure. In some embodiments, the electronic device 100 shown in FIG. 2A is formed on a bare substrate (not illustrated) in layers. In one or more embodiments, the electronic device of FIG. 2A is made up of a substrate 170, a first sacrificial layer 102, a second sacrificial layer 104, and a memory stack 106.

The substrate 170 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, a first sacrificial layer 102 is on a substrate 170, and a second sacrificial layer 104 is on the first sacrificial layer 102. The first sacrificial layer 102 may comprise any suitable material known to the skilled artisan. In one or more embodiments, the first sacrificial layer 102 comprises an insulating layer. In one or more embodiments, the first sacrificial layer 102 comprises silicon nitride (SiN).

The second sacrificial layer 104 may also be referred to as the semiconductor material layer or the active layer. As used herein, the term “active” or “memory layer” refers to a layer of material in which a channel, a bit line, a word line, or a capacitor can be made. In one or more embodiments, the active layer comprises one or more of silicon or doped silicon.

The second sacrificial layer 104 can be formed by any suitable technique known to the skilled artisan and can be made from any suitable material. In some embodiments, the semiconductor material may be a doped material, such as n-doped silicon (n-Si), or p-doped silicon (p-Si). In some embodiments, the semiconductor material may be doped using any suitable process such as an ion implantation process. As used herein, the term “n-type” refers to semiconductor material layer that is created by doping with an electron donor element during manufacture. The term n-type comes from the negative charge of the electron. In n-type semiconductor material layers, electrons are the majority carriers and holes are the minority carriers. As used herein, the term “p-type” refers to the positive charge of a well (or hole). As opposed to n-type semiconductor materials, p-type semiconductor materials have a larger hole concentration than electron concentration. In p-type semiconductor materials, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the second sacrificial layer 104 comprises several different conductive or semiconductor materials.

The first sacrificial layer 102 and the second sacrificial layer 104 may formed on a substrate 170 and can be made of any suitable material. In some embodiments, one or more of the first sacrificial layer 102 and the second sacrificial layer 104 may be removed and replaced in later processes. In some embodiments, one or more of the first sacrificial layer 102 and the second sacrificial layer 104 are not removed and remain within the memory device 100. In this case, the term “sacrificial” has an expanded meaning to include permanent layers and may be referred to as the conductive layer. In one or more embodiments, one or more of the first sacrificial layer 102 and the second sacrificial layer 104 comprise a material that can be removed selectively versus the layers of the neighboring memory stack 106.

The memory stack 106 in the illustrated embodiment comprises a plurality of alternating first material layers 108, second material layers 110, first sacrificial layers 102, and second sacrificial layers 104. While the memory stack 106, illustrated in FIG. 2A, has a single set of alternating first material layers 108, second material layers 110, first material layers 108, second material layers 110, first sacrificial layers 102, and second sacrificial layers 104, one of skill in the art recognizes that this is merely for illustrative purposes only. The memory stack 106 may have any number of alternating first material layers 108, second material layers 110, first sacrificial layers 102, and second sacrificial layers 104. For example, in some embodiments, the memory stack 106 comprises 192 pairs of alternating first material layers 108, second material layers 110, first sacrificial layers 102, and second sacrificial layers 104. In other embodiments, the memory stack 106 comprises greater than 50 pairs of alternating first material layers 108, second material layers 110, first sacrificial layers 102, and second sacrificial layers 104, or greater than 100 pairs of alternating first material layers 108, second material layers 110, first sacrificial layers 102, and second sacrificial layers 104, or greater than 300 pairs of alternating first material layers 108, second material layers 110, first sacrificial layers 102, and second sacrificial layers 104.

In one or more embodiments, sequential depositions are used to form many active area regions. In one or more embodiments, alternating layers of films, e.g., oxide-polysilicon, polysilicon-nitride, oxide-nitride, silicon-silicon germanium, are deposited.

In one or more embodiments, the first material layers 108 and the second material layers 110 independently comprise an insulating material. In one or more embodiments, the first material layers 108 comprise nitride layers and the second material layers 106 comprise oxide layers. In some embodiments, the memory stack 106 comprises a non-replacement gate such as alternating oxide and poly-silicon (OP), or oxide and metal, or oxide and sacrificial layer. The second layers 110 comprise a material that is etch selective relative to the first layers 108 so that the second layers 110 can be removed without substantially affecting the first layers 108. In one or more embodiments, the first layers 108 comprise silicon nitride (SiN). In one or more embodiments, the second layers 110 comprise silicon oxide (SiOₓ). In one or more embodiments first layers 108 and second layers 110 are deposited by chemical vapor deposition (CVD) or physical vapor deposition (PVD).

The individual alternating layers may be formed to any suitable thickness. In some embodiments, the thickness of each second layer 110 is approximately equal. In one or more embodiments, each second layer 110 has a second layer thickness. In some embodiments, the thickness of each first layer 108 is approximately equal. As used in this regard, thicknesses which are approximately equal are within +/−5% of each other. In some embodiments, a silicon layer (not shown) is formed between the second layers 110 and first layers 108. The thickness of the silicon layer may be relatively thin as compared to the thickness of a layer of second layers 110 or first layers 108. In one or more embodiments, the first layers 108 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the first layer 108 has a thickness in the range of from about 0.5 to about 40 nm. In one or more embodiments, the second layers 110 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments, the second layer 110 has a thickness in the range of from about 0.5 to about 40 nm.

Referring to FIG. 2B, the device is patterned to form an active opening 210. In some embodiments, patterning the active opening 150 comprises etching through the memory stack 106, first sacrificial layer 102, second sacrificial layer 104, and into substrate 170. Referring to FIG. 2B, the active opening 210 has sidewalls that extend through the memory stack 106 exposing surfaces of the second material layers 110 and surfaces of the first material layers 108.

The first sacrificial layer 102 and the second sacrificial layer 104 have surfaces exposed as sidewalls of the active opening 210. The active opening 210 extends a distance into the substrate 170 so that sidewall surface and bottom of the active opening 210 are formed within the substrate 170. The bottom of the active opening 210 can be formed at any point within the thickness of the substrate 170. In some embodiments, the active opening 210 extends a thickness into the substrate 170 in the range of from about 10% to about 90%, or in the range of from about 20% to about 80%, or in the range of from about 30% to about 70%, or in the range of from about 40% to about 60% of the thickness of the substrate 102. In some embodiments, the active opening 210 extends a distance into the substrate 170 by greater than or equal to 10%, 20%, 30%, 40%, 50%, 60%, 70% or 80% of the thickness of the substrate 170.

Referring to FIG. 2C, the first sacrificial layer 102 and the first material layers 108, e.g., nitride layers, are selectively recessed through the active opening 210 to form a recessed region 116. In one or more embodiments, the second material layers 110, e.g., nitride layers, are recessed through the active opening 210 using a reactive species that is formed via a remote plasma from a process gas comprising oxygen (O₂) and nitrogen trifluoride (NF₃). In other embodiments, the second material layers 110, e.g., nitride layers, are recessed through the active opening 210 using hot phosphorus (HP).

With reference to FIG. 2D, a gate oxide layer 114 is deposited through the active opening 210 onto the second sacrificial layer 104. The gate oxide layer 114 may comprise any suitable material known to the skilled artisan. The gate oxide layer 114 can be deposited using one or more deposition techniques known to the skilled artisan. In one or more embodiments, the gate oxide layer 114 is deposited using one of deposition techniques, such as, but not limited to, ALD, CVD, PVD, MBE, MOCVD, spin-on, or other deposition techniques known to the skilled artisan. The illustrated embodiment shows the gate oxide layer 114 as a conformal layer with a uniform shape. However, the skilled artisan will recognize that this is merely for illustrative purposes and that the gate oxide layer 114 can form in an isotropic manner so that the gate oxide layer 114 has a rounded appearance. In some embodiments, the gate oxide layer 114 is selectively deposited as a conformal layer on the surface of the second sacrificial layer 104. In some embodiments, the gate oxide 114 is formed by oxidation of the semiconductor surface.

In one or more embodiments, gate oxide layer 114 comprises a silicon oxide (SiOₓ). While the term “silicon oxide” may be used to describe the gate oxide layer 114, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g., silicon nitride, silicon oxynitride, tungsten oxide, zirconium oxide, aluminum oxide, hafnium oxide, and the like.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

Referring to FIG. 2E, the word lines are formed. The word lines comprise one or more of a barrier layer 116 and a word line metal 118. The oxide layer 114 may comprise any suitable material known to the skilled artisan. The barrier layer 116 may comprise any suitable material known to the skilled artisan. In one or more embodiments, the barrier layer 116 comprises one or more of titanium nitride (TiN), tantalum nitride (TaN), or the like. In one or more embodiments, the word line metal 118 comprises a bulk metal comprising one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the word line metal 118 comprises tungsten (W). In other embodiments, the word line metal 184 comprises ruthenium (Ru).

FIG. 2F shows operation 40 of method 10 where the active opening 210 is filled with a fill material 120. The fill material 120 may be any suitable material known to one of skill in the art. In one or more embodiments, the fill material 120 comprises one or more of a dielectric material. As used herein, the term “dielectric material” refers to a layer of material that is an electrical insulator that can be polarized in an electric field. In one or more embodiments, the dielectric material comprises one or more of oxides, carbon doped oxides, silicon oxide (SiO), porous silicon dioxide (SiO₂), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH).

FIG. 2G shows operation 45 of method 10, where the device is slit patterned to form slit pattern openings 122 that extend from a top surface of the memory stack 106 to the substrate 170.

FIG. 2H shows operations 50 and 55 of method 10, where the capacitor openings 124 are formed and the second sacrificial layer 104 and the polysilicon layer 105 are recessed through the slit pattern opening 122. This process may also be referred to as a “pull back” process. In one or more embodiments, the process shown in FIG. 2H is a poly-silicon pull back.

FIG. 2I shows operation 60 of method 10, where a metal silicide layer 126 is formed in the opening 124 on the second sacrificial layer 104. The metal silicide layer 126 may be formed by any suitable technique known to the skilled artisan. In one or more embodiments, the metal silicide layer 126 is selectively deposited through the capacitor opening 124 onto the polysilicon layer 105. For example, selective tungsten (W) or tungsten silicide (WSiₓ) can be deposited on the silicon (Si) surface using tungsten fluoride (WF₆) and hydrogen (H₂).

In one or more embodiments, the metal silicide layer 126 comprises a metal. The metal may be any suitable metal known to the skilled artisan. In one or more embodiments, the metal is selected from one or more of titanium (Ti), tantalum (Ta), tungsten (W), ruthenium (Ru), iridium (Ir), and molybdenum (Mo). Thus, in one or more embodiments, the metal silicide layer 126 comprises one or more of titanium silicide (TiSi), tantalum silicide (TaSi), tungsten silicide (WSi), ruthenium silicide (RuSi), iridium silicide (IrSi), and molybdenum silicide (MoSi).

Without intending to be bound be theory, it is thought that the presence of the metal silicide layer 126 leads to formation of a contact having low resistance. In some embodiments, the metal silicide layer 126 may lower the resistance in an amount in a range of from 0.5 to 0.01 when compared to a 3D DRAM device that does not have a metal silicide layer.

FIGS. 2J through 2N show operation 65 of method 10, where the capacitor 180 is formed. In FIG. 2J, the opening 124 is enlarged prior to forming the capacitor to create a widened capacitor opening 128. The opening 124 can be widened by any suitable technique known to the skilled artisan. After the opening 124 has been widened to widened capacitor opening 128, a capacitor 180 is formed within, as shown in FIGS. 2K through 2M. The capacitor opening 124 of some embodiments is widened by a percentage of a thickness of the active region 105. In some embodiments, the capacitor opening 124 is widened by an amount in the range of 10% to 80% of the thickness of the active region 105. In some embodiments, the capacitor opening 124 is widened by an amount in the range of 20% to 75%, or in the range of 30% to 60%. In some embodiments, the capacitor opening 124 is widened using a dilute HF (˜1% HF in water) wet etch. In some embodiments, widening the capacitor opening results in an increase in capacitor surface area in the range of 1% to 85%, or in the range of 5% to 80%, or in the range of 10% to 75%, or in the range of 20% to 60%.

FIGS. 2K through 2N, show a capacitor 180 formed in the widened capacitor opening 128 adjacent the recessed polysilicon layer 105. In some embodiments, the capacitor is formed by first depositing a lower electrode 130 in the capacitor opening 128. The lower electrode 130, also referred to as a bottom electrode or bottom contact, can be formed by any suitable technique known to the skilled artisan. In some embodiments, the lower electrode 130 is a conformal film deposited by atomic layer deposition. In one or more embodiments, the lower electrode 130 comprises a material selected from one or more of copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt), and metal nitrides of any of the fore-going metals. For example, in one or more embodiments, the lower electrode 130 comprises a material selected from one or more of copper nitride, cobalt nitride, tungsten nitride, titanium nitride, molybdenum nitride, nickel nitride, ruthenium nitride, silver nitride, gold nitride, iridium nitride, tantalum nitride, or platinum nitride. In some embodiments, the capacitor comprises a bottom electrode, a capacitor dielectric, and a top electrode. In some embodiments, the capacitor comprises a double layer. For example, the top electrode and a titanium nitride plus silicon germanium double layer.

In some embodiments, forming the capacitor comprises depositing one or more of a lower electrode, a high-κ dielectric layer, a top electrode, and a silicon germanium (SiGe) layer.

Referring to FIG. 2L, a high-κ dielectric 132 is deposited on the lower electrode 130 within the capacitor opening 128. The high-κ dielectric 132 of some embodiments comprises hafnium oxide. In some embodiments, the high-κ dielectric 132 is deposited as a conformal film by atomic layer deposition. Referring to FIG. 2M, a top electrode 134 is formed in the capacitor opening 128 within the high-κ dielectric 132. The top electrode 134, also referred to as a top contact or upper electrode, can be formed by any suitable technique known to the skilled artisan. In one or more embodiments, the top electrode 134 comprises a conductive material comprising one or more of copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt), and metal nitrides of any of the fore-going metals. For example, in one or more embodiments, the lower electrode 130 comprises a material selected from one or more of copper nitride, cobalt nitride, tungsten nitride, titanium nitride, molybdenum nitride, nickel nitride, ruthenium nitride, silver nitride, gold nitride, iridium nitride, tantalum nitride, or platinum nitride. In some embodiments, not illustrated, a dielectric is deposited to fill any open space remaining in the capacitor opening 128 after formation of the top electrode 130. The dielectric of some embodiments separates the individual unit cells from adjacent unit cells to prevent shorting.

In one or more embodiments, with reference to FIG. 2N, the slit pattern opening 122 is filled with a silicon germanium (SiGe) layer 136 to form capacitor 180 on trop electrode 130.

FIG. 2O shows operation 70 of method 10, where a bit line hole 138 (also referred to as a bit line opening) is formed. In some embodiments, the electronic device is patterned to form a plurality of bit line holes 138. The bit line hole 138 can be formed by any suitable technique known to the skilled artisan. In some embodiments, the bit line hole 138 is formed by positioning a patterned hard mask and etching the dielectric 120 through the hard mask.

In one or more embodiments, referring to FIG. 2P, the second sacrificial layer 104 and the polysilicon layer 105 are doped, e.g., by a gas phase doping process. The gas phase doping process forms a doped layer 140 on the outer edge of the polysilicon layer 105 and the second sacrificial layer 104. In some embodiments, doping is performed during deposition of the polysilicon layer 105 material using a dopant source. For example, a phosphorous doped silica glass (PSG) or boron phosphorous doped glass (BPSG) is diffused into the material. In some embodiments, the doped layer 140 has a thickness in the range of from about 1 nm to about 20 nm (measured from the outer edge of the polysilicon layer 105 toward the bit line opening 138).

FIG. 2Q illustrates operation 75 of method 10, where a bit line 142 is formed in the bit line hole 138. In one or more embodiments, the bit line 142 may include an optional bit line liner (also referred to as a bit line barrier layer) and a bit line metal.

The optional bit line liner can be made of any suitable material deposited by any suitable technique known to the skilled artisan. In some embodiments, the bit line liner is conformally deposited in the plurality of bit line holes 138 and deposited on an exposed surface of the dielectric 120 and the doped surface 140 (or exposed surface) of the active material 105. In one or more embodiments, the bit line liner is deposited on the source/drain region at the inner end of the active material 105. The bit line liner can be any suitable material including, but not limited to, titanium nitride (TiN) or tantalum nitride (TaN). In some embodiments, the optional bit line liner comprises or consists essentially of titanium nitride (TiN). As used in this manner, the term “consists essentially of” means that the composition of the film is greater than or equal to about 95%, 98%, 99% or 99.5% of the stated species. In some embodiments, the optional bit line liner comprises or consists essentially of tantalum nitride (TaN). In some embodiments, the bit line liner is a conformal layer. In some embodiments, the bit line liner is deposited by atomic layer deposition.

In some embodiments, the bit line 142 comprises a bit line metal. The bit line metal may comprise any suitable metal known to the skilled artisan. In one or more embodiments, the bit line metal comprises or consists essentially of one or more of tungsten silicide (WSi), tungsten nitride (WN), or tungsten (W). The bit line metal can be deposited by any suitable technique known to the skilled artisan and can be any suitable material. In one or more embodiments, forming the bit line 142 further comprises forming a bit line metal seed layer (not shown) prior to depositing the bit line metal.

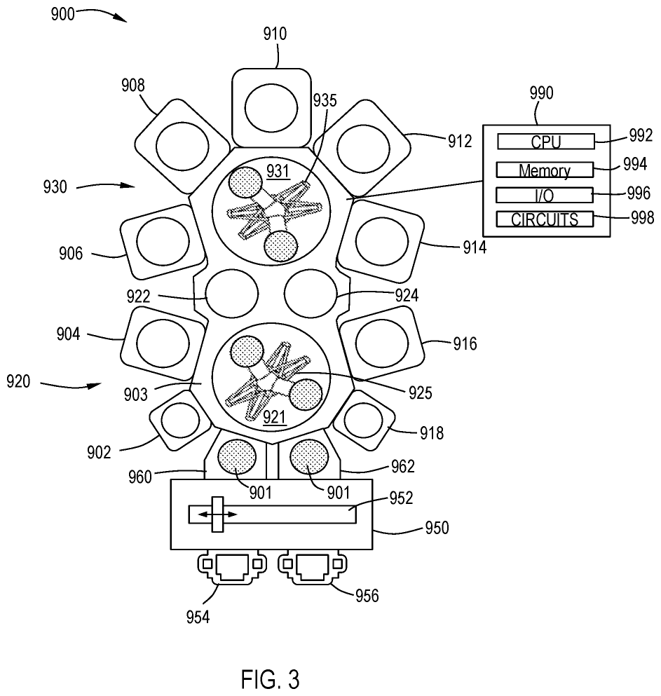

Additional embodiments of the disclosure are directed to processing tools 900 for the formation of the memory devices and methods described, as shown in FIG. 3. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a selective etching chamber, and the like. The particular arrangement of process chambers and components can be varied depending on the cluster tool and should not be taken as limiting the scope of the disclosure.

In the embodiment shown in FIG. 3, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU), memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a memory device, the method comprising:
forming a metal silicide layer on a semiconductor material layer on a memory stack, the semiconductor material layer having a capacitor side and a bit line side;
forming a capacitor on the capacitor side of the metal silicide layer; and
forming a bit line on the bit line side of the metal silicide layer.

2. The method of claim 1, wherein the memory stack comprises a sacrificial layer, and alternating layers of a first material layer, a second material layer, and the semiconductor material layer.

3. The method of claim 2, wherein first material layer and the second material layer independently comprise an insulating material.

4. The method of claim 3, wherein the first material layer comprises a nitride layer and the second material layer comprises an oxide layer.

5. The method of claim 4, wherein the first material layer comprises silicon nitride and the second material layer comprises silicon oxide.

6. The method of claim 1, wherein the semiconductor material layer comprises poly-silicon.

7. The method of claim 1, wherein the metal silicide layer comprises a metal selected from one or more of titanium (Ti), tantalum (Ta), tungsten (W), ruthenium (Ru), iridium (Ir), and molybdenum (Mo).

8. The method of claim 1, wherein forming the capacitor comprises depositing one or more of a lower electrode, a high-κ dielectric layer, a top electrode, and a silicon germanium (SiGe) layer.

9. A method of forming a memory device, the method comprising:
forming a memory stack, the memory stack comprising a sacrificial layer, and alternating layers of a first material layer, a second material layer, and a semiconductor material layer;
forming an active opening through the memory stack and recessing the first material layer through the active opening to form a recessed region;
depositing a gate oxide layer on the second material layer;
forming a word line in the recessed region, the word line comprising one or more of a barrier layer and a word line metal;
depositing a fill material in the active opening;
forming a slit pattern opening through the memory stack;
forming a capacitor opening by recessing the second material layer and the semiconductor material layer through the slit pattern opening;
forming a metal silicide layer on the semiconductor material layer;
forming a capacitor in the capacitor opening;
forming a bit line opening in the fill material; and
forming a bit line in the bit line opening.

10. The method of claim 9, wherein the first material layer and the second material layer independently comprise an insulating material.

11. The method of claim 10, wherein the first material layer comprises a nitride layer and the second material layer comprises an oxide layer.

12. The method of claim 11, wherein the first material layer comprises silicon nitride and the second material layer comprises silicon oxide.

13. The method of claim 9, wherein the semiconductor material layer comprises poly-silicon.

14. The method of claim 9, wherein the metal silicide layer comprises a metal selected from one or more of titanium (Ti), tantalum (Ta), tungsten (W), ruthenium (Ru), iridium (Ir), and molybdenum (Mo).

15. The method of claim 9, wherein forming the capacitor comprises depositing one or more of a lower electrode, a high-κ dielectric layer, a top electrode, and a silicon germanium (SiGe) layer.

16. A non-transitory computer readable medium including instructions, that, when executed by a controller of a processing chamber, causes the processing chamber to perform the operations of:
form a memory stack, the memory stack comprising a sacrificial layer, and alternating layers of a first material layer, a second material layer, and a semiconductor material layer;
form an active opening through the memory stack and recessing the first material layer through the active opening to form a recessed region;
deposit a gate oxide layer on the second material layer;
form a word line in the recessed region, the word line comprising one or more of a barrier layer and a word line metal;
deposit a fill material in the active opening;
form a slit pattern opening through the memory stack;
form a capacitor opening by recessing the second material layer and the semiconductor material layer through the slit pattern opening;
form a metal silicide layer on the semiconductor material layer;
form a capacitor in the capacitor opening;
form a bit line opening in the fill material; and
form a bit line in the bit line opening.

17. The non-transitory computer readable medium of claim 16, wherein the first material layer comprises silicon nitride, the second material layer comprises silicon oxide, and the semiconductor material layer comprises poly-silicon.

18. The non-transitory computer readable medium of claim 16, wherein the metal silicide layer comprises a metal selected from one or more of titanium (Ti), tantalum (Ta), tungsten (W), ruthenium (Ru), iridium (Ir), and molybdenum (Mo).

19. A method of forming a semiconductor device, the method comprising:
forming a film stack on a substrate, the film stack comprising a plurality of alternating layers of a semiconductor material layer and a dielectric layer;
patterning the film stack to form an opening, the opening extending from a top surface of the film stack to the substrate and having an aspect ratio of greater than or equal to 10:1;
recessing the semiconductor material layer through the opening to form a recessed semiconductor material layer; and
selectively depositing a metal layer on the recessed semiconductor material layer.

20. The method of claim 19, wherein the metal layer comprises a metal selected from one or more of titanium (Ti), tantalum (Ta), tungsten (W), ruthenium (Ru), iridium (Ir), and molybdenum (Mo).
